(19) United States
(12) Patent Application Publication
(10) Pub. No.: US 2025/0327870 A1
(43) Pub. Date: Oct. 23, 2025

(54) BATTERY SYSTEM

(71) Applicant: TOYOTA JIDOSHA KABUSHIKI KAISHA, Toyota-shi (JP)

(72) Inventors: Mai FUJIWARA, Handa-shi (JP); Yuji Nishi, Nagoya-shi (JP)

(73) Assignee: TOYOTA JIDOSHA KABUSHIKI KAISHA, Toyota-shi (JP)

(21) Appl. No.: 19/003,290

(22) Filed: Dec. 27, 2024

(30) Foreign Application Priority Data
Apr. 17, 2024 (JP) 2024-066743

(51) Int. Cl. G01R 31/388

(52) U.S. Cl. CPC G01R 31/388

(57) ABSTRACT

The full charge capacity is calculated by adding the cumulative current amount from the time of the maximal value detection to the full charge to the reference capacity in which the change amount of the average value of the second corrected voltage is the maximal value. The first corrected voltage is calculated by subtracting the concentration overvoltage from the voltage of the cell. Based on the relationship between the first corrected voltage and the charge and discharge current in the predetermined period, the second corrected voltage, which is the first corrected voltage when the charge and discharge current is zero, is calculated by extrapolation or interpolation. An average value of the second corrected voltages is calculated, and a change amount of the average value is obtained. Then, the maximal value of the change amount is detected, and the full charge capacity is calculated.

### CROSS-REFERENCE TO RELATED APPLICATION

This application claims priority to Japanese Patent Application No. 2024-066743 filed on Apr. 17, 2024, incorporated herein by reference in its entirety.

### BACKGROUND

### 1. Technical Field

The present disclosure relates to battery systems.

### 2. Description of Related Art

Japanese Unexamined Patent Application Publication No. 2014-167457 (JP 2014-167457 A) describes detecting a singularity that is a maximal value of a voltage change amount of a secondary cell during charging and discharging, and estimating capacity of the secondary cell based on the singularity.

### SUMMARY

In JP 2014-167457 A, a voltage between the terminals of each secondary cell included in an assembled battery is detected using a voltage measuring circuit. Polarization occurs during charging and discharging of the secondary cell. Therefore, the voltage detected by the voltage measuring circuit includes a deviation due to the polarization. In particular, polarization due to a concentration overvoltage occurs with a lag from an increase or decrease in charge and discharge current. Therefore, accuracy of the singularity obtained using the cell voltage detected by the voltage measuring circuit may decrease. This may reduce estimation accuracy of the capacity of the secondary cell.

It is an object of the present disclosure to accurately estimate the capacity (full charge capacity) of a battery.

(1) A battery system of the present disclosure is a battery system including: a battery; a voltage sensor configured to detect a battery voltage that is a voltage of the battery; a current sensor configured to detect a charge and discharge current of the battery; and a control device.

The control device includes
a current cumulating unit configured to compute a cumulative discharge current value that is a cumulative value of a discharge current of the battery,
a concentration overvoltage calculating unit configured to acquire a concentration overvoltage of the battery,
a first corrected voltage calculating unit configured to calculate a first corrected voltage by subtracting the concentration overvoltage from the battery voltage detected by the voltage sensor, and
a maximal value detecting unit configured to detect a maximal value of a voltage change amount based on the first corrected voltage. The control device is configured to estimate a full charge capacity of the battery based on a first cumulative current value. The first cumulative current value is the cumulative discharge current value from when the battery is fully charged until the maximal value is detected.

In this configuration, the maximal value detecting unit detects the maximal value of the voltage change amount based on the first corrected voltage. The full charge capacity of the battery is estimated based on the first cumulative current value that is the cumulative discharge current value from when the battery is fully charged until the maximal value is detected. Since the first corrected voltage is a voltage obtained by subtracting the concentration overvoltage from the battery voltage detected by the voltage sensor, the maximal value is detected without the influence of polarization due to the salt concentration overvoltage. The full charge capacity can therefore be accurately estimated.

(2) A battery system of the present disclosure is a battery system including: a battery; a voltage sensor configured to detect a battery voltage that is a voltage of the battery; a current sensor configured to detect a charge and discharge current of the battery; and a control device.

The control device includes
a current cumulating unit configured to compute a cumulative charge current value that is a cumulative value of a charge current of the battery,
a concentration overvoltage calculating unit configured to acquire a concentration overvoltage of the battery, a first corrected voltage calculating unit configured to calculate a first corrected voltage by subtracting the concentration overvoltage from the battery voltage detected by the voltage sensor, and
a maximal value detecting unit configured to detect a maximal value of a voltage change amount based on the first corrected voltage. The control device is configured to estimate a full charge capacity of the battery based on a second cumulative current value. The second cumulative current value is the cumulative charge current value from when the maximal value is detected until the battery is fully charged.

In this configuration, the maximal value detecting unit detects the maximal value of the voltage change amount based on the first corrected voltage. The full charge capacity of the battery is estimated based on the second cumulative current value that is the cumulative charge current value from when the maximal value is detected until the battery is fully charged. Since the first corrected voltage is a voltage obtained by subtracting the concentration overvoltage from the battery voltage detected by the voltage sensor, the maximal value is detected without the influence of polarization due to the salt concentration overvoltage. The full charge capacity can therefore be accurately estimated.

In the above (1) or (2), the control device may further include a second corrected voltage estimating unit configured to estimate a second corrected voltage based on the first corrected voltage in a predetermined period. The second corrected voltage may be a value of the first corrected voltage when the charge and discharge current is zero. The maximal value detecting unit may be configured to detect the maximal value based on the second corrected voltage.

In this configuration, the second corrected voltage estimating unit estimates the second corrected voltage, namely the value of the first corrected voltage when the charge and discharge current is zero, based on the first corrected voltage in the predetermined period.

The second corrected voltage is the voltage when the charge and discharge current of the battery is zero. Therefore, the value of the second corrected voltage does not include the influence of polarization due to an overvoltage caused by resistances such as cathode reaction resistance, anode reaction resistance, electrolyte solution resistance, and IR loss. The maximal value detecting unit detects the maximal value based on the second corrected voltage. Since the maximal value is thus detected in consideration of the polarization caused by the resistances, the full charge capacity can be more accurately estimated.

The full charge capacity may be calculated based on a reference capacity that is a capacity of the battery at the maximal value.

The maximal value appears at approximately the same remaining capacity of the battery regardless of the deterioration state etc. of the battery. The remaining capacity when the maximal value appears is set as the reference capacity. Accordingly, the full charge capacity can be accurately estimated by adding the first cumulative current value or the second cumulative current value to the reference capacity.

The battery may have a characteristic that there is a plurality of the maximal values, and the reference capacity may be a capacity of the battery at the maximal value corresponding to a higher voltage of the battery.

The longer the cumulative time of the charge and discharge current (the larger the cumulative amount of the charge and discharge current), the more detection errors of the current sensor etc. are also cumulated, and therefore the lower the accuracy of the cumulative value of the charge and discharge current. In the above configuration, the capacity at the maximal value corresponding to a higher voltage of the battery is set as the reference capacity. Therefore, the cumulative time (cumulative amount) of the first cumulative current value or the second cumulative current value can be relatively reduced, and the estimation accuracy of the full charge capacity can be improved.

According to the present disclosure, it is possible to accurately estimate the capacity (full charge capacity) of a battery.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is an entire configuration diagram of an electrified vehicle in which a battery system according to the present embodiment is mounted;

FIG. 2 is a diagram showing the relation between OCV and the remaining capacity in the cell (LFP cell) of the present embodiment;

FIG. 3 is a flow chart illustrating an example of a charge full charge capacity estimation process performed by ECU;

FIG. 4 is a flowchart illustrating an example of a change amount ΔVBSav calculation routine executed in ECU;

FIG. 5 is a flow chart of a charge and discharge current cumulating routine executed in ECU; and

FIG. 6 is a flowchart illustrating an example of a discharge full charge capacity estimation process performed by ECU.

### DETAILED DESCRIPTION OF EMBODIMENTS

Hereinafter, an embodiment of the present disclosure will be described in detail with reference to the drawings. In the drawings, the same or corresponding parts are denoted by the same reference numerals, and the description thereof will not be repeated.

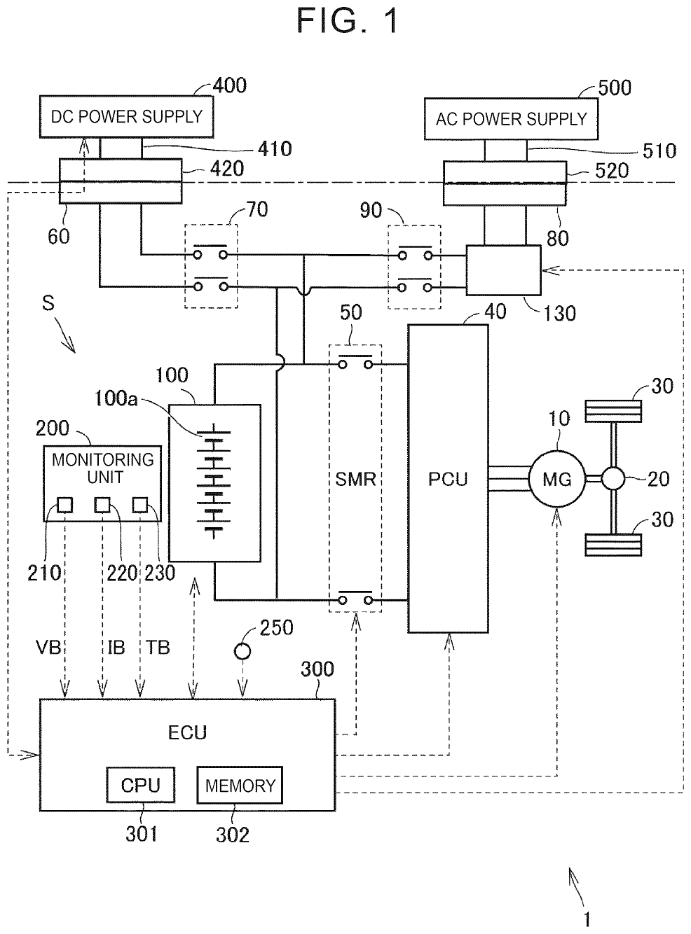

FIG. 1 is an entire configuration diagram of an electrified vehicle 1 in which a battery system S according to the present embodiment is mounted. In the present 15 embodiment, electrified vehicle 1 is, for example, a battery electric vehicle. Electrified vehicle 1 includes a motor generator (MG: Motor Generator) 10 which is a rotary electric machine, power transmission gears 20, drive wheels 30, a power control unit (PCU: Power Control Unit) 40, a system main relay (SMR: System Main Relay) 50, a battery 100, a monitoring unit 200, and an electronic control unit (ECU: Electronic Control Unit) 300 which is an example of a control device.

MG 10 is, for example, an interior permanent magnet synchronous motor (IPM motor), and has a function as an electric motor and a function as a generator. The output torque of MG 10 is transmitted to the drive wheels 30 via the power transmission gears 20 including a speed reducer, a differential, and the like.

When electrified vehicle 1 is braked, MG 10 is driven by the drive wheels 30, and MG 10 operates as a generator. As a result, MG 10 also functions as a braking device that performs regenerative braking for converting kinetic energy of electrified vehicle 1 into electric power. Regenerated electric power generated by regenerative braking force in the MG 10 is stored in the battery 100.

The PCU 40 is a power conversion device that bidirectionally converts electric power between the MG 10 and the battery 100. The PCU 40 includes an inverter and a converter that operate, for example, based on a control signal from the ECU 300.

When the battery 100 is discharged, the converter boosts voltage supplied from the battery 100 and supplies the boosted voltage to the inverter. The inverter converts DC power which is supplied from the converter into AC power and drives the MG 10.

When the battery 100 is charged, the inverter converts AC power generated by MG 10 into DC power and supplies the DC power to the converter. The converter steps down voltage supplied from the inverter to voltage suitable for charging the battery 100 and supplies the stepped-down voltage to the battery 100.

The SMR 50 is electrically connected to power lines connecting the battery 100 and the PCU 40. If SMR 50 is ON in response to a control signal from ECU 300, power may be transferred between the battery 100 and PCU 40. On the other hand, when SMR 50 is OFF in response to a control signal from ECU 300, the battery 100 is disconnected from PCU 40.

The battery 100 stores electric power for driving MG 10. The battery 100 is a rechargeable DC power supply (secondary battery), and is configured by stacking a plurality of cells (battery cells) 100a and electrically connecting them in series, for example. The battery 100 and the cell 100a correspond to the “cell” of the present disclosure. The cell 100a may comprise, for example, a lithium-ion cell. In the present embodiment, an iron phosphate lithium-ion battery (LFP battery) in which lithium iron phosphate is used as a positive electrode active material is employed as the cell 100a.

The monitoring unit 200 includes a voltage sensor 210, a current sensor 220, and a temperature sensor 230. The voltage sensor 210 detects a voltage VB (a voltage VB between terminals of the cell 100a) of the cell 100a. The current sensor 220 detects a current IB input to and output from the battery 100 (cell 100a). The current IB may be positive (+) for the current charging the battery 100 and negative (−) for the current discharged from the battery 100. The temperature sensor 230 detects a temperature TB of each of the cell 100a. The detecting units output the results of this detection to the ECU 300.

Electrified vehicle 1 includes a DC inlet 60, and the battery 100 can be rapidly charged from an external direct current (DC) power supply that is a charging facility. DC inlet 60 is configured to be connectable to a connector 420 provided at a distal end of the charging cable 410 of the external DC power supply (charging facility) 400. The charging relay 70 is electrically connected to a power line connecting DC inlet 60 and the battery 100. The charging relay 70 switches between supplying and shutting off power between DC inlet 60 and the battery 100 in response to a control signal from ECU 300. When the charging relay 70 is closed, external charging (quick charging) of the battery 100 is performed.

Electrified vehicle 1 includes a AC inlet 80, and the battery 100 can be normally charged from an external alternating current (AC) power supply, which is a charging facility. AC inlet 80 is configured to be connectable to a connector 520 provided at a distal end of the charging cable 510 of the external AC power supply (charging facility) 500. A in-vehicle charger 130 is provided in a power line between AC inlet 80 and the battery 100, and converts AC power supplied from an external AC power supply into DC power and converts the battery 100 into a chargeable voltage. The charging relay 90 is electrically connected to a power line connecting the in-vehicle charger 130 and the battery 100. The charging relay 90 switches between supplying and shutting off the electric power between the in-vehicle charger 130 and the battery 100 in response to a control signal from ECU 300. When the charging relay 90 is closed, external charging (normal) of the battery 100 is performed.

The ECU 300 includes a central processing unit (CPU) 301, and a memory (including, for example, a read only memory (ROM) and a random access memory (RAM)) 302. ECU 300 controls the devices so that electrified vehicle 1 is in a desired condition based on the signals received from the monitoring unit 200, signals from various sensors (not shown), maps and programs stored in the memories 302, and the like. The signals from the various sensors are, for example, an accelerator operation amount signal, a vehicle speed signal, and the like. In addition, ECU 300 executes a charge full charge capacity estimation process and the like. The battery system S includes a battery 100 (cell 100a), a monitoring unit 200, an ECU 300, and the like.

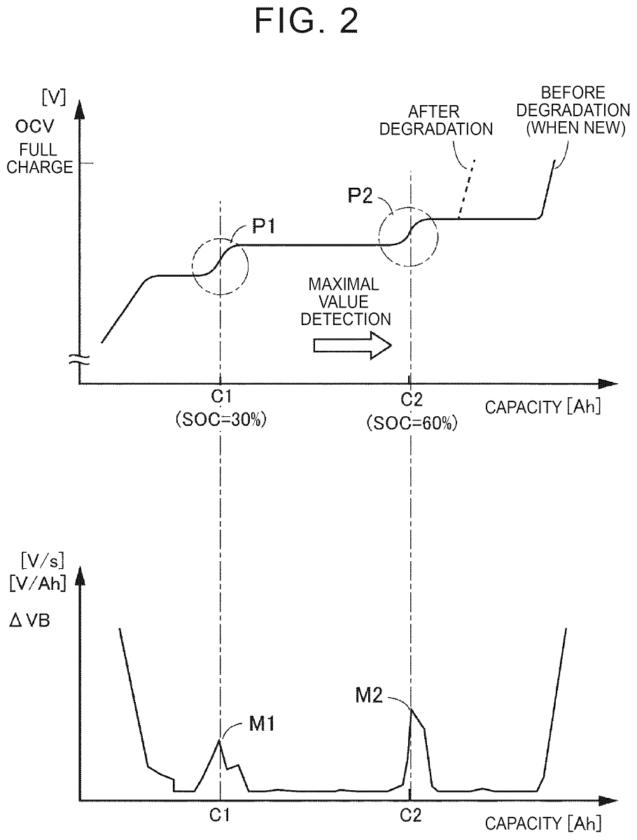

FIG. 2 is a diagram showing the relation between OCV (Open Circuit Voltage) and the remaining capacitance in the cell 100a (LFP cell) of the present embodiment. In the upper graph of FIG. 2, the vertical axis represents OCV (V) of the cell 100a, and the horizontal axis represents the remaining capacity (charge capacity) (Ah) of the cell 100a. As shown in the upper graph of FIG. 2, the relationship between OCV and the remaining capacitance (hereinafter, this relationship is also referred to as a OCV curve) has a wide range of regions (voltage flat regions) in which the change of OCV curve is minute. When a portion where OCV curve is increased from the voltage flat region and becomes the voltage flat region again is referred to as a “step”, in the cell 100a of the present embodiment, there are two step P1, P2.

In the step P1 of the first stage (OCV is lower), SOC (State Of Charge) of the cell 100a at the time of a new product exists in the vicinity of 30%. In the step P2 of the second stage (OCV is higher), SOC of the cell 100a at the time of a new product exists in the vicinity of about 60%. As shown by a broken line in the upper graph of FIG. 2, these steps do not change the position of the steps even when the full charge capacity of the cell 100a decreases (when the capacity retention rate of the cell 100a decreases) due to degradation of the cell 100a. Even if the cell 100a deteriorates, the residual capacitance at which the step appears does not change.

The lower graph of FIG. 2 shows the relationship between the voltage change amount ΔVB of the voltage VB at the time of charging of the battery 100 and the remaining capacity, and shows the relationship when charging or discharging at a constant current. The voltage change amount ΔVB is a change amount (V/Ah) of the voltage VB with respect to the remaining capacity (charge capacity) or a change amount (V/s) of the voltage VB with respect to the time (charge time or discharge time). As illustrated in the lower graph of FIG. 2, the voltage change amount ΔVB becomes a maximal value M1 in the remaining capacity corresponding to the step P1, and becomes a maximal value M2 in the remaining capacity corresponding to the step P2. Therefore, the remaining capacity in which the voltage change amount ΔVB becomes the maximal value M1 is stored as the reference capacity C1, and the charge current from the time when the voltage change amount ΔVB becomes the maximal value M1 until the full charge is cumulated. By adding the cumulative value and the reference capacity C1, the full charge capacity of the battery 100 (single cell 100a) can be estimated. Alternatively, the discharge current from the time when the battery 100 (single cell 100a) is fully charged to the time when the voltage change amount ΔVB reaches the maximal value M1 is cumulated. By adding the cumulative value and the reference capacity C1, the full charge capacity of the battery 100 (single cell 100a) can be estimated.

Further, the remaining capacity in which the voltage change amount ΔVB becomes the maximal value M2 is stored as the reference capacity C2, and the charge current from when the voltage change amount ΔVB becomes the maximal value M2 until the full charge is cumulated. By adding the cumulative value and the reference capacity C2, the full charge capacity of the battery 100 (single cell 100a) can be estimated. Alternatively, the discharge current from the time when the battery 100 (single cell 100a) is fully charged to the time when the voltage change amount ΔVB reaches the maximal value M2 is cumulated. By adding the cumulative value and the reference capacity C2, the full charge capacity of the battery 100 (single cell 100a) can be estimated.

The cumulative value of the charge and discharge current is cumulated with the detection error or the like of the current sensor 220 as the cumulative time becomes longer (as the cumulative amount becomes larger), so that the accuracy thereof deteriorates. In the present embodiment, the maximal value M2 corresponding to the step P2 of the second stage (OCV is higher) is detected, the charge current from the time when the maximal value M2 is reached until the full charge is reached is cumulated, and/or the discharge current from the time of the full charge until the maximal value M2 is detected is cumulated. In the present embodiment, in order to improve the estimation accuracy of the full charge capacity, the full charge capacity is estimated in this manner.

Polarization occurs when the battery 100 (cell 100a) is charged and discharged. Therefore, the voltage VB detected by the voltage sensor 210 during charging and discharging becomes smaller by the overvoltage. The polarization includes an overvoltage caused by resistances such as cathode reaction resistance, anode reaction resistance, electrolyte resistance, and IR loss in the cell 100a, and an overvoltage caused by an electromotive voltage system such as a positive electrode diffusion, a negative electrode diffusion, and a concentration overvoltage (salt concentration overvoltage). In particular, since the polarization caused by the concentration overvoltage is delayed with respect to the increase or decrease of the charge and discharge current, when the voltage change amount ΔVB is calculated using the voltage VB and the maximal value M2 is obtained, the detecting accuracy may be lowered. When the accuracy of detecting the maximal value M2 decreases, the accuracy of calculating the “cumulative value of the charge current from the maximal value M2 to the full charge” and the “cumulative value of the discharge current from the full charge time to the maximal value M2” decreases, and the accuracy of estimating the full charge capacity decreases.

In the present embodiment, by subtracting the concentration overvoltage from the voltage VB detected by the voltage sensor 210, a decrease in the detection accuracy of the maximal value M2 is suppressed, and the full charge capacity can be accurately estimated.

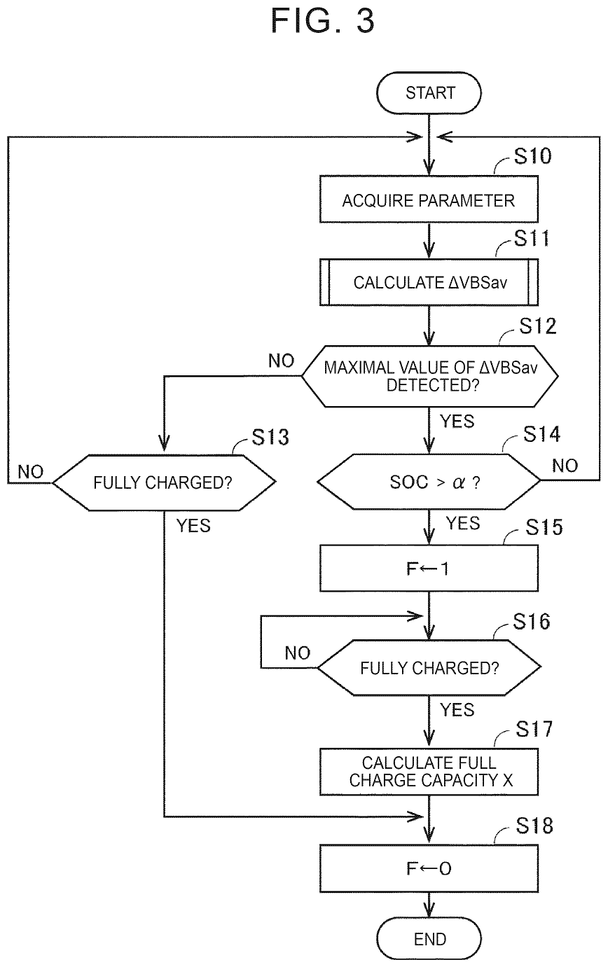

FIG. 3 is a flow chart illustrating an example of a charge full charge capacity estimation process performed by ECU 300. This flow chart is executed when external charging of the battery 100 is started, and is executed for each cell 100a. The connector 420 is connected to DC inlet 60, and ECU 300 acquires various parameters in a step (hereinafter, step is abbreviated as “S”) 10. Alternatively, when the connector 520 is connected to AC inlet 80 and external charging of the battery 100 is started, ECU 300 acquires various parameters in the step S10. The various parameters may be, for example, a voltage BV, a current IB, a temperature TB, and the like detected by the monitoring unit 200.

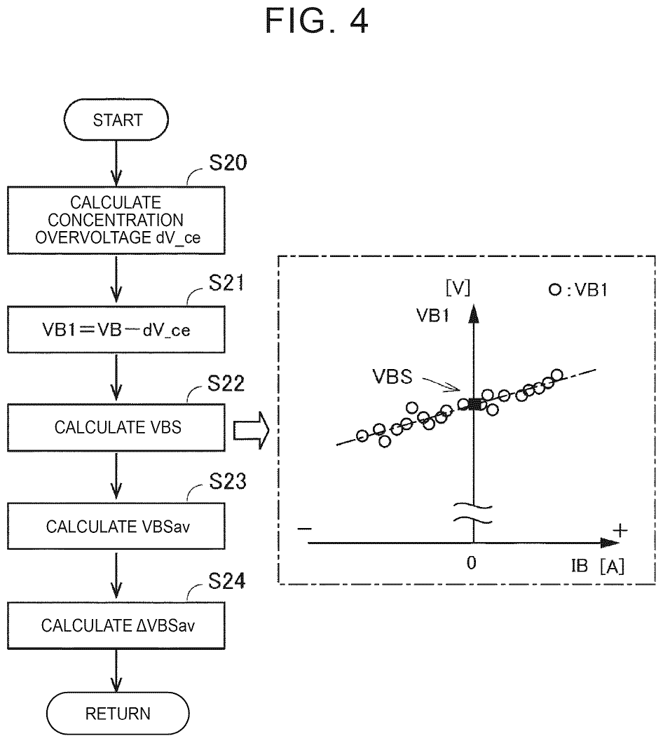

In the following S11, the change amount ΔVBSav of the average value VBSav of the second corrected voltage VBS is calculated. The change amount ΔVBSav is calculated by a change amount ΔVBSav calculation routine. FIG. 4 is a flow chart showing an example of a change amount ΔVBSav calculation routine executed by ECU 300. This flowchart is repeatedly processed at the set timing at the same time as the start of the full charge estimation process.

Referring to FIG. 4, in S20, the concentration overvoltage (salt concentration overvoltage) dV_ce of the cell 100a is calculated. The concentration overvoltage dV_ce may be calculated from, for example, a first-order lag equation of “dV_ce=(1−α)×dV_ce (previous value)−β×IB (where α and β are the matching values)”. The initial value of the concentration overvoltage dV_ce may be 0 (zero). The concentration overvoltage dV_ce may be calculated from a known diffusion equation.

In the following S21, the first corrected voltage VB1 is calculated by subtracting the concentration overvoltage dV_ce from the voltage VB (VB1=VB−dV_ce). In S22, the second corrected voltage VBS is calculated. The second corrected voltage VBS is a value obtained by estimating the first corrected voltage VB1 when the current IB (charge and discharge current of the cell 100a) is 0 (zero) from the first corrected voltage VB1 in a predetermined period (for example, 30 seconds). For example, as shown in the graph to the right of FIG. 4, the first corrected voltage VB1 and the current IB are plotted in a predetermined period. Then, the first corrected voltage VB1 when the current IB is 0 (zero) is obtained by interpolation or extrapolation using the linear function (straight line), and the second corrected voltage VBS is calculated.

In S23, the average value VBSav of the second corrected voltage VBS is calculated. In the present embodiment, the average value VBSav is a simple moving average of the second corrected voltage VBS, and may be a simple moving average of n second corrected voltages VBS including the current second corrected voltage VBS (VBSav=VBSav (previous value)−VBS (n+1)/n+VBS/n, where VBS(n+1) is the value of VBS that is (n+1) times before). For example, n may be 10.

In the following S24, the change amount ΔVBSav of the average value VBSav of the second corrected voltage VBS is calculated. The change amount ΔVBSav may be a change amount (V/Ah) of the average value VBSav of the second corrected voltage VBS with respect to the remaining capacity (charge capacity), and may be a change amount (V/s) of the average value VBSav with respect to the time (charge time). When the change amount ΔVBSav is calculated, the present routine is ended, the process is started from S20, and the calculation of the next change amount ΔVBSav is started.

Referring to FIG. 3, S12 determines whether the maximal value of the change amount ΔVBSav has been detected. The maximal value may be detected when the current change amount ΔVBSav becomes a small value with respect to the previous change amount ΔVBSav. Alternatively, the maximal value may be detected when the sign of the differential value of the change amount ΔVBSav changes from positive to negative. In S13, when the maximal value of the change amount ΔVBSav is not detected, the process proceeds to S13, and when the maximal value of the change amount ΔVBSav is detected, the process proceeds to S14.

In S13, it is determined whether or not the battery 100 (cell 100a) is fully charged. For example, if the battery 100 is performing CCCV (Constant Current-Constant Voltage) charging, it may be determined that the battery is fully charged when the charge current falls below a set value. Alternatively, it may be determined that the battery 100 is fully charged when the voltage VB of any of the cell 100a reaches the charge termination voltage. When it is determined that the battery 100 is fully charged, the process proceeds to S18. If the battery is not fully charged, S10 returns.

In S14, it is determined whether or not SOC of the cell 100a is larger than a predetermined value α. The predetermined value α is a value set to determine that the maximal value detected by S12 corresponds to the maximal value M2 (see the lower graph of FIG. 2), and may be, for example, 50 (%). SOC is a SOC of the cell 100a at the time of a new product, and may be measured by, for example, a Coulomb count method. In S14, when SOC is equal to or less than the predetermined value α, the maximal value detected by S12 corresponds to the maximal value M1 (refer to the lower graph of FIG. 2), so that a negative determination is made, and the process returns to S10. When SOC is larger than the predetermined value α (SOC>α), since the maximal value detected by S12 corresponds to the maximal value M2, an affirmative determination is made, and the process proceeds to S15.

In S15, after the flag F1 is set to 1, the process proceeds to S16. The initial value of the flag F is set to 0. In S16, it is determined whether or not the battery 100 (cell 100a) is fully charged. S16 is repeatedly processed until the battery is fully charged, and when the battery 100 is fully charged, an affirmative determination is made, and the process proceeds to S17.

In S17, the full charge capacity X of the cell 100a is calculated. The full charge capacity X is calculated by adding the cumulative current amount ΣQa to the reference capacity C2 (X=C2+ΣQa).

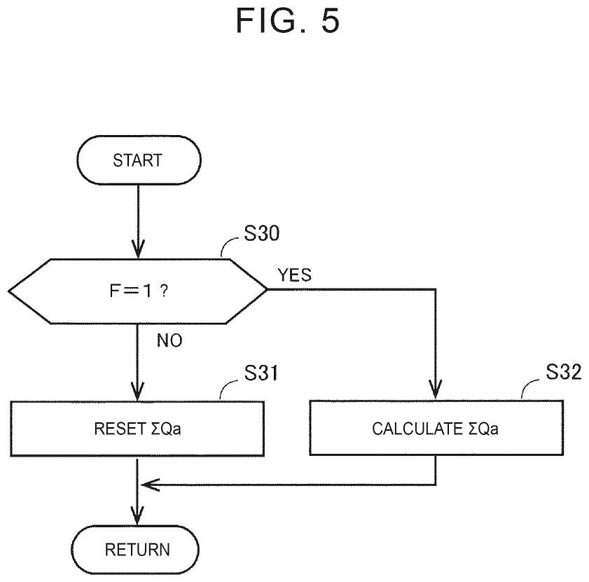

FIG. 5 is a flow chart of a charge and discharge current cumulating routine executed by ECU 300. This flowchart is executed when external charging of the battery 100 is started. Further, the flow chart is repeatedly processed at predetermined intervals when electrified vehicle 1 power switch is turned ON and electrified vehicle 1 is allowed to travel (when the battery system S is enabled). First, in S30, it is determined whether or not the flag F is 1. When the flag F is 0, a negative determination is made, and the process proceeds to S31 to reset the cumulative current value ΣQa (cumulative current value ΣQa is set to 0). When the flag F is 1, an affirmative determination is made, and the process proceeds to S32, where the charge and discharge current is cumulated to calculate the cumulative current value ΣQa. For example, the cumulative current value ΣQa is calculated by cumulating the current IB detected by the current sensor 220, and the cumulative current value ΣQa is calculated as an absolute value (positive value). Since the charge current is cumulated during the external charging of the battery 100, the cumulative current value ΣQa becomes the cumulative value of the charge current.

As shown in FIG. 2, the reference capacity C2 is the remaining capacity (charge capacity) of the cell 100a at the maximal value M2 (step P2), and is set in advance by experimentation or the like. The cumulative current value Qa used when calculating the full charge capacity X of S17 is a cumulative current value from when the maximal value corresponding to the extreme value M2 of the change amount ΔVBSav is detected until the full charge is reached. Therefore, the full charge capacity X of the cell 100a can be calculated by adding the cumulative current value Qa to the reference capacity C2. The cumulative current value Qa used in S17 is an example of the “second cumulative current value” disclosed herein.

After calculating the full charge capacity X by S17, the process proceeds to S18. In S18, after the flag F is set to 0, the current full charge capacity estimation process is ended.

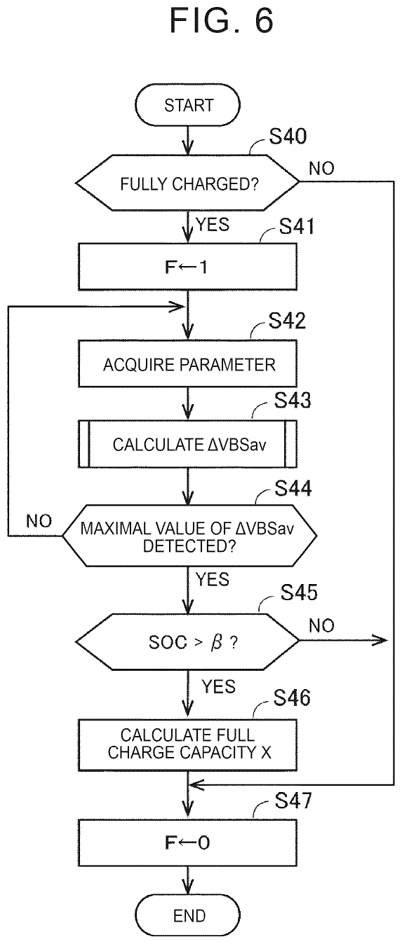

FIG. 6 is a flowchart illustrating an example of a discharge full charge capacity estimation process performed by ECU 300. This flowchart is executed for each cell 100a when the power switch of the electrified vehicle 1 is turned on and the electrified vehicle 1 is ready to travel. In S40, it is determined whether or not the battery 100 (cell 100a) is fully charged. For example, when the voltage VB is equal to or higher than a predetermined voltage corresponding to the full charge, it may be determined that the charge is full. When the power switch is turned ON, if the battery is fully charged, an affirmative determination is made, and the process proceeds to S40, and if the battery is not fully charged, a negative determination is made, and the process proceeds to S47.

In S41, after the flag F is set to 1, the process proceeds to S42 to acquire various parameters. S42 and S43 are similar processes to S10 and S11 of FIG. 3. However, the change amount ΔVBSav in S43 is calculated by starting the change amount ΔVBSav calculation routine of FIG. 4 at the same time as ON of the power switch. Further, the concentration overvoltage (salt concentration overvoltage) dV_ce calculated by S21 of FIG. 4 is calculated from the first order delay equation of dV_ce=(1−α)×dV_ce (previous value)+β×IB. Further, the change amount ΔVBSav calculated by S24 (FIG. 4) is a change amount (V/Ah) of the average value VBSav of the second corrected voltage VBS with respect to the remaining capacity.

In S44, it is determined whether the maximal value of the change amount ΔVBSav has been detected. In S44, the same process as in S12 (FIG. 3) is performed, and when the maximal value of the change amount ΔVBSav is not detected, the process returns to step 42, and when the maximal value of the change amount ΔVBSav is detected, the process proceeds to S45.

In S45, it is determined whether or not SOC of the cell 100a is greater than a predetermined value β. The predetermined value β is a value set to determine that the maximal value detected by S12 corresponds to the maximal value M2 (see the lower graph of FIG. 2), and may be the same value as the predetermined value α in S14 (FIG. 3). When SOC is equal to or less than the predetermined value β, a negative determination is made, and the process proceeds to S47. If SOC is greater than the predetermined value β, an affirmative determination is made, and the process proceeds to S46.

In S46, the full charge capacity X of the cell 100a is calculated. The full charge capacity X is calculated by adding the cumulative current amount ΣQa to the reference capacity C2 as in S17 (X=C2+ΣQa). In the discharge full charge capacity estimation process, when the battery 100 (cell 100a) is fully charged, the flag F is set to 1 (S41). Therefore, the cumulative current value Qa used in the calculation of the full charge capacity X of S46 is a cumulative current value from the full charge state until a maximal value corresponding to the extreme value M2 of the change amount ΔVBSav is detected. Therefore, the full charge capacity X of the cell 100a can be calculated by adding the cumulative current value Qa to the reference capacity C2. The cumulative current value Qa used in S46 is an example of the “first cumulative current value” of the present disclosure.

After calculating the full charge capacity X by S46, the process proceeds to S47. In S47, after the flag F is set to 0, the current discharge full charge capacity estimation process is ended.

In the above embodiment, the process of FIG. 5 (charge and discharge current cumulating routine) is an example of the “current cumulating unit” of the present disclosure, and the process of S20 (FIG. 4) is an example of the “concentration overvoltage calculating unit” of the present disclosure. S21 process is an example of the “first corrected voltage calculating unit” of the present disclosure, and S22 process is an example of the “second corrected voltage estimating unit” of the present disclosure. Further, the processes of S12 (FIGS. 3) and S44 (FIG. 6) are an example of the “maximal value detecting unit” of the present disclosure.

In the above embodiment, the maximal value of the voltage change amount is detected by using the change amount ΔVBSav of the average value VBSav of the second corrected voltage VBS. However, using the change amount ΔVB1 (V/Ah) of the first corrected voltage VB1. The maximal value of the voltage change amount may be detected. Alternatively, the maximal value of the voltage change amount may be detected by using the change amount ΔVBS (V/Ah) of the second corrected voltage VBS.

According to the present embodiment, the first corrected voltage VB1 is a voltage obtained by the concentration overvoltage dV_ce from the voltage VB detected by the voltage sensor 210, and the maximal value M2 can be detected relatively accurately. Further, since the second corrected voltage VBS is the first corrected voltage VB1 when the charge and discharge current is zero, the influence of the overvoltage (polarization) caused by resistances can be eliminated, and the maximal value M2 can be accurately detected. Further, since the maximal value M2 is detected by using the change amount ΔVBSav of VBSav which is the moving average of the second corrected voltage VBS, the influence of noises etc. during detection of the voltage VB can be eliminated, and the maximal value M2 can be accurately detected.

In the above embodiment, an iron phosphate lithium-ion battery (LFP battery) is employed as the cell 100a. However, the cell 100a may be other types of cells as long as there is a small area (voltage flat area) in which the change in OCV curve is small and the maximal value of the voltage change amount can be detected. Further, the maximal value M1 may be detected, and the full charge capacity may be calculated using the reference capacity C1.

The embodiment disclosed herein shall be construed as illustrative in all respects and not restrictive. The scope of the present disclosure is defined not by the above description of the embodiments but by the claims, and is intended to include all possible modifications within a scope equivalent in meaning and scope to the claims.

What is claimed is:

1. A battery system comprising:
a battery;
a voltage sensor configured to detect a battery voltage that is a voltage of the battery;
a current sensor configured to detect a charge and discharge current of the battery; and
a control device, wherein:
the control device includes
a current cumulating unit configured to compute a cumulative discharge current value that is a cumulative value of a discharge current of the battery,
a concentration overvoltage calculating unit configured to acquire a concentration overvoltage of the battery,
a first corrected voltage calculating unit configured to calculate a first corrected voltage by subtracting the concentration overvoltage from the battery voltage detected by the voltage sensor, and
a maximal value detecting unit configured to detect a maximal value of a voltage change amount based on the first corrected voltage; and
the control device is configured to estimate a full charge capacity of the battery based on a first cumulative current value, the first cumulative current value being the cumulative discharge current value from when the battery is fully charged until the maximal value is detected.

2. A battery system comprising:
a battery;
a voltage sensor configured to detect a battery voltage that is a voltage of the battery;
a current sensor configured to detect a charge and discharge current of the battery; and
a control device, wherein:
the control device includes
a current cumulating unit configured to compute a cumulative charge current value that is a cumulative value of a charge current of the battery,
a concentration overvoltage calculating unit configured to acquire a concentration overvoltage of the battery,
a first corrected voltage calculating unit configured to calculate a first corrected voltage by subtracting the concentration overvoltage from the battery voltage detected by the voltage sensor, and
a maximal value detecting unit configured to detect a maximal value of a voltage change amount based on the first corrected voltage; and
the control device is configured to estimate a full charge capacity of the battery based on a second cumulative current value, the second cumulative current value being the cumulative charge current value from when the maximal value is detected until the battery is fully charged.

3. The battery system according to claim 1, wherein:
the control device further includes a second corrected voltage estimating unit configured to estimate a second corrected voltage based on the first corrected voltage in a predetermined period, the second corrected voltage being a value of the first corrected voltage when the charge and discharge current is zero; and
the maximal value detecting unit is configured to detect the maximal value based on the second corrected voltage.

4. The battery system according to claim 2, wherein:
the control device further includes a second corrected voltage estimating unit configured to estimate a second corrected voltage based on the first corrected voltage in a predetermined period, the second corrected voltage being a value of the first corrected voltage when the charge and discharge current is zero; and
the maximal value detecting unit is configured to detect the maximal value based on the second corrected voltage.

5. The battery system according to claim 3, wherein the full charge capacity is calculated based on a reference capacity that is a capacity of the battery at the maximal value.

6. The battery system according to claim 5, wherein:
the battery has a characteristic that there is a plurality of the maximal values; and
the reference capacity is a capacity of the battery at the maximal value corresponding to a higher voltage of the battery out of the maximal values.

7. The battery system according to claim 4, wherein the full charge capacity is calculated based on a reference capacity that is a capacity of the battery at the maximal value.

8. The battery system according to claim 7, wherein:
the battery has a characteristic that there is a plurality of the maximal values; and
the reference capacity is a capacity of the battery at the maximal value corresponding to a higher voltage of the battery out of the maximal values.
